(19) United States
(12) Patent Application Publication
(10) Pub. No.: US 2015/0243852 A1
(43) Pub. Date: Aug. 27, 2015

(54) LED chip-on-board component and lighting module

(71) Applicant: LUMICHIP LIMITED, Hong Kong (HK)

(72) Inventor: Juha Rantala, Hong Kong (HK)

(21) Appl. No.: 14/426,393

(22) PCT Filed: Sep. 9, 2013
(86) PCT No.: PCT/FI2013/050867

§ 371 Date: Mar. 6, 2015

(30) Foreign Application Priority Data
Sep. 8, 2012 (FI) 20125934

(51) Int. Cl. H01L 33/48; H01L 33/62; H01L 33/64; H01L 33/50; H01L 33/36; H01L 33/52

(52) U.S. Cl. CPC H01L 33/486; H01L 33/36; H01L 33/52; H01L 33/642; H01L 33/507; H01L 33/62; H01L 33/647

(57) ABSTRACT

An object of the present invention is to provide a Light Emitting Diode (LED) construction. It is an object of certain embodiments of the present invention to provide an LED Chip-on-Board (COB) construction comprising, a thermally and electrically conductive substrate, at least one semiconductor light emitting die or diode and an electrically insulating material. It is an aspect of certain embodiments that the at least one semiconductor light emitting die bonded to the thermally and electrically conductive substrate. Additionally, the construction comprises an anode or cathode electrode on the insulating material, wherein said anode or cathode electrodes are wire bonded to a first side of the semiconductor light emitting die's electrical contact, and the opposite side of the semiconductor light emitting chip is either anode or cathode. Furthermore, wherein the semiconductor device is encapsulated with an optical encapsulate. The present invention has particular use with red and far red spectrum LED constructions.

### FIELD OF THE INVENTION

The present invention relates generally to Light Emitting Diode (LED) lighting components, light engines, lamps and luminaries which are increasingly used as light sources in various lighting applications. Some of the significant advantages to LED's over conventional lighting elements are their significantly lower power consumption, the absence of harmful chemicals and their outstanding lifetime.

Industrial applications utilize LEDs of different power levels in various applications having different levels of technical challenges and limitations. High power LEDs (>1 W) are used mainly in applications where high level of lumen output is required from constrained size. Typical applications are filament bulb replacements for power levels of 40 W and up, spot lights, track lights etc. Medium power LEDs are used on applications for example where different light guides are used for producing even light output on large surfaces.

Some technical challenges connected with the manufacture of LED's still exist. In order to produce high performance and reliable light emitting diodes and components, issues of cost, thermal management and management of glare need to be properly addressed. In addition safety requirements may need to be fulfilled, setting demands on various support structures, power supplies and their insulation.

### BACKGROUND OF THE INVENTION

Thermal management is a challenge especially with high power density LEDs such as Chip-On-Board (COB) LEDs. The luminous output of an LED or LED COB is related to its temperature. A high temperature lowers the optical output power of an LED. The junction temperature in a LED is a function of the electrical power driven into the LED, the ratio of power turned into heat, and thermal resistance to heat dissipation. Main factors affecting the thermal resistance of LEDs are its internal thermal resistance, the thermal resistance of electrical interconnections, the thermal resistance of any heat dissipating (heat sink) structures, and the heat convection capability of the LED's encapsulation. The sum of all thermal resistances in a component together with the thermal power or heat generated, defines how much the temperature rises in the component over the ambient temperature.

A common problem in semiconductor components is the limited heat conductivity of their electrical interconnections. Typically, electrical interconnections on PCB's are of some tens of micrometers thick layers of copper, silver or their alloys. These thin interconnections are poor heat conductors and do not conduct the heat effectively away from the interconnection. An interconnection with a width of 1 mm and a thickness of 35 μm provides a heat transferring cross sectional area of only 0.035 mm². Generally speaking, poor thermal conductivity at the interconnections requires a large area heat sink.

LED's are often assembled on a metal core printed circuit board (MCPCB), or on aluminum substrate, which is connected to a ceramic, plastic or aluminum heat sink. Ceramic heat sinks make it possible to use different thick film methods to manufacture the interconnections directly on top of the heat sink. Plastic heat sinks are used mainly with MCPCBs for relatively low power solutions. After the heat has been conducted through the thermal interfaces between the heat dissipating body and the PCB or MCPCB into its aluminum plate, further heat conduction is done from the bottom of the PCB, enhanced by different thermal interface materials and different fastening methods, e.g. screws.

To increase the thermal conductivity, LED components are often provided with a separate thermal pad underneath the semiconductor component. This causes a need for an extra insulating gap on the pad side of the LED, as the two electrical pads need to be insulated with gaps from the thermal pad. This extra insulating gap shrinks down the heat conducting surface area underneath the LED, where the limitations on heat conductivity are most severe and where the heat densities are the highest.

Heat conduction can be improved by using so-called thermal slugs or heat pads which improve the thermal connection from the component to the MCPCB and to heat sinks, including plastic heat sinks. However, the heat conduction still remains very limited due to the size of the aforementioned electrical connections and the cross-sectional area of the component.

Combining plastic materials with PCB typically requires expensive thermal adhesives or greases that require complicated assembly techniques. Form factor problems are also inherent as MCPCB and ceramic PCB are flat and rigid by their nature, making the process of constructing a LED lamp costly and complex as it includes various components, e.g. one or more LEDs, PCB, thermal interface materials, fasteners such as screws, additional heat sink structures such as heat pipes. Traditional low cost plastics cannot be applied, as high cost and complex to process thermally conductive composites are mandatory to use.

In many LED lighting applications several high power LEDs need to be placed in close configuration. Such applications are, e.g. spot lights, chip on board LED module structures etc. The heat generating components, their power supplies, the PCBs, the thermal interface materials and solutions, the fixing structures and heat dissipating bodies, all together dictate the achievable performance level in the lighting application. The amount of lumens achievable from the application is a function of the heat transfer capacity of the structure.

Current drawbacks of an LED lamp made with a plastic casing and with a conventional PCB substrate faces at least the following problems: thermal transfer limitations of the PCB and the plastic body result in heat build-up, increasing LED component temperature, lower LED efficacy and shortened life. These multipart solutions also create challenges for recyclability, e.g. when a great variety of materials are integrated into one, which is at least partially directed by legislation for LED components to be more or less impossible to be opened easily.

Plants, crops, animals and humans are proven to benefits for certain parts of UV, visible and near infrared (NIR) spectrum. Various chemical substances may absorb the energy of the emitted spectrum and may use the energy in photochemical, chemical reaction or otherwise physically active cell activity. These reactions are well known in the photosynthesis process in plants. However, it is also indicated that certain specific spectra can improve wound healing or activate cell growth.

Artificial lighting for plant cultivation is an important factor which determines the cost and nutritional quality of greenhouse vegetables. Efficiency of greenhouse lighting has been improved by the application of high-pressure sodium (HPS) lamps which emit predominantly yellow-red light which is effectively absorbed by chlorophylls. The improvement is achieved owing to a high overall light yield and the emission spectrum suitable for plant cultivation. However, the application of light sources with a spectrum substantially different from the solar spectrum encounters difficulties owing to the sensitivity of plants to the spectral composition of light. Particularly, in HPS lamps designed for horticulture applications, the blue component can be enhanced; however, a further purposeful tailoring of the spectrum in the red wavelength region of the HPS lamps has limitations. In principle, the spectrum can be adjusted using different phosphors, but data on the spectrum optimal for particular plants are still scarce and fragmental and cannot be optimized.

Light-emitting diodes (LEDs) present a versatile alternative for artificial greenhouse lighting with numerous advantages. In comparison with conventional HPS and fluorescent lamps, LEDs are an energy-efficient, environmentally friendly and long lasting source of light. Assembling already available LED's from the entire relevant spectral range from near infrared (IR) to near ultraviolet (UV), enables one to tailor the spectrum for optimal growth. Particularly the spectra in the red and far-red regions are essential for successful and efficient plant cultivation, typically described as 660 nm region wavelengths contributing most for the photosynthesis and 730 nm region wavelengths contributing most for photomorphogenesis in plants. These types of spectra can be obtained by direct electro-luminescence from AlGaAs or AlInGaP semiconductor LEDs or using blue emitting high power (HP) LED which blue light is then converted to RED wavelength with phosphors materials.

The application of light therapy with LEDs will significantly improve the medical care that is available to astronauts on long-term space missions based on NASA experiments. LEDs stimulate the basic energy processes in the mitochondria (energy compartments) of each cell, particularly when near-infrared light is used to activate the color sensitive chemicals (chromophores, cytochrome systems) inside. Proposed Optimal LED wavelengths include 680, 730 and 880 nm and those have improved the healing of wounds in laboratory animals. Furthermore, DNA synthesis in fibroblasts and muscle cells has been quintupled using NASA LED light alone, in a single application combining 680, 730 and 880 nm each at 4 Joules per centimeter squared.

The light is absorbed by mitochondria where it stimulates energy metabolism in muscle and bone, as well as skin and subcutaneous tissue. Also, lasers provide low energy stimulation of tissues which results in increased cellular activity during wound healing including increased fibroblast proliferation, growth factor synthesis, collagen production and angiogenesis. Lasers, however, have some inherent characteristics that make their use in a clinical setting problematic, such as limitations in wavelength capabilities and beam width. The combined wavelengths of light optimal for wound healing cannot be efficiently produced, and the size of wounds that may be treated by lasers is limited. Light-emitting diodes (LEDs) offer an effective alternative to lasers with human and animal populations include treatment of serious burns, crush injuries, non-healing fractures, muscle and bone atrophy, traumatic ischemic wounds, radiation tissue damage, compromised skin grafts, and tissue regeneration.

There are several applications that benefit from the availability of efficient and correct spectrum red and far red LEDs. However, producing efficient broad band red and far LEDs devices with optimal spectral emission for various forms of light therapy and plant cultivation remains problematic. In particular, the problem arises when broad emission spectrum is beneficial and required at red and/or far red wavelength regions. All phosphorescent materials are sensitive to heat and particularly the phosphorescent materials that result in long stokes shift emission. Similarly to phosphorescent materials, quantum dot nanoparticles particles such as CdSe—ZnS (core-shell) semiconductor crystals can be used to produce wavelength conversion for shorter wavelengths to higher wavelengths. These wavelength conversion materials are also sensitive to thermal quenching. Red and far red emission can be also be produced by using, for example, AlGaAS semiconductor LEDs. However typically these devices, in order to be efficient, result in relatively narrow emission spectrum with narrow less than 50 nm full width of half maximum.

### SUMMARY OF INVENTION

An object of the present invention is to provide a Light Emitting Diode (LED) construction.

It is an object of certain embodiments of the present invention to provide an LED Chip-on-Board (COB) construction comprising, a thermally and electrically conductive substrate, at least one semiconductor light emitting die or diode and an electrically insulating material.

It is an aspect of certain embodiments that the at least one semiconductor light emitting die bonded to the thermally and electrically conductive substrate. Additionally, the construction comprises an anode or cathode electrode on the insulating material, wherein said anode or cathode electrodes are wire bonded to a first side of the semiconductor light emitting die's electrical contact, and the opposite side of the semiconductor light emitting chip is either anode or cathode. Furthermore, wherein the semiconductor device is encapsulated with an optical encapsulate.

Several examples are provided wherein the optical encapsulate contains wavelength conversion material. Additionally, the thermally and electrically conductive substrate can be a metal sheet. Still further, the thermally and electrically conductive substrate can have at least one alignment marking, preferably two, and the electrically insulating material has at least one, preferably two corresponding marking opening. The thermally and electrically conductive substrate and/or the electrically insulating material can at least one central opening.

Furthermore, it is an object of certain embodiments of the present invention to provide a Light Emitting Diode (LED) lamp construction comprising at least one light emitter component, a primary heat sink, and a secondary heat sink.

According to certain embodiments, the primary heat sink is in direct contact with the light emitter component, said primary heat sink formed of a material having a first thermal conductivity, and the secondary heat sink is intimately bonded to at least a portion of the primary heat sink, said secondary heat sink formed from at least one material having a second thermal conductivity.

It is an aspect of certain embodiments that the primary heat sink is electrically insulated from the environment. Significant advantage is obtained by having a primary heat sink in direct contact with a light emitter component, such as a light emitting diode, and simultaneously electrically insulated from the environment. Direct contact between the die or diode and the primary heat sink allows for the most efficient heat transfer, thus more effectively cooling the element. This effect is particularly effective when the primary heat sink is a good thermal and even good electrical conductor. This direct contact between an electrical component such as the light emitting element and a good thermal and electrical conductor such as the primary heat sink is made possible by the electrically insulated nature of the primary heat sink. Thus, shorts are able to be eliminated and an effective heat dissipating construction is made possible. Numerous advantages are further realized by an LED construction having superior thermal dissipation properties from the light emitting element.

According to certain examples an LED lamp is provided further comprising a dielectric material on at least a first face of the primary heat sink containing the light emitter component, said dielectric material at least partially surrounding said light emitter component. Additionally, the construction may further comprise electrical connections mounted on the dielectric material and connected to said light emitter component.

Still further, it is an object of certain embodiments of the present invention to provide a Light Emitting Diode (LED) lamp construction comprising, at least one light emitter component, a primary heat sink formed of a material having a first thermal conductivity, a secondary heat sink, intimately bonded to at least a portion of the primary heat sink, said secondary heat sink formed from at least one material having a second thermal conductivity, a dielectric material partially covering a first surface of the primary heat sink and said dielectric material supporting the at least one light emitter component, a volume between the component and the first surface of the primary heat sink which is void of dielectric material which thermally exposes the component to the primary heat sink, and wherein the primary heat sink is electrically insulated from the environment.

Provided herein are embodiments and examples wherein a light emitter is bonded indirectly to the primary heat sink. Similar to the discussion above, by electrically insulating the primary heat sink from the environment it is possible to expand the variety of constructions where the light emitter is bonded indirectly to the primary heat sink. High thermal conductivity adhesives, which may also be good electrical conductors, can be used to bond the light emitter to a thermally and electrically conductive primary heat sink without risk.

The invention will be described in more detail below with the aid of the drawings and examples.

### BRIEF DESCRIPTION OF THE DRAWINGS

FIG. 1 shows an example of a COB module according to example 1.

FIG. 2 shows an example of a COB module according to example 2.

FIG. 3 shows an example of a COB module according to example 3.

FIG. 4 shows an LED lighting module utilizing a COB in accordance with, for example, the module of FIG. 1.

FIG. 5a shows a cutaway of a LED lamp having an LED mounted above a primary heat sink.

FIG. 5b shows a cutaway of an LED lamp having an LED mounted directly to a primary heat sink.

FIG. 6a shows a cutaway of an LED lamp having an LED mounted on contacts on an insulator later above a primary heat sink.

FIG. 6b shows a cutaway similar to the example of FIG. 6a having insulator sections supporting the LED.

### DETAILED EXPLANATION OF EXEMPLARY EMBODIMENTS

Described herein is an LED Chip-On-Board (COB) component comprising a heat conductive die bonding substrate, a light emitting semiconductor die or chip, electrical circuitry containing an insulating material, a light conversion material and optional optical elements. Additionally described is a light module comprising a COB component wherein the lighting module is at least partially electrically insulating and the COB module is attached to the electrically insulating part of the light module. The electrically insulating part of the lighting module can also be (e.g. moulded or printed) one or both sides of the high thermal conductivity parts of the COB component.

A primary heat sink and a secondary heat sink are disclosed, wherein the primary heat sink can be electrically and thermally conductive and the secondary heat sink is at least partially only heat conductive. The primary heat sink can be a bonding substrate for the semiconductor light emitting diode's (epi chip or die) anode and cathode contacts. The secondary substrate can be a bonding substrate for the COB component, wherein the COB component, or portion thereof can be, for example, the primary heat sink.

A secondary substrate can also be part of the lighting module mechanical construction or body and electrically insulates the COB component from the ambient environment. According to certain examples the COB component is only electrically connected from an anode and a cathode to DC or AC circuitry, e.g. LED driver or AC-DC converter.

According to aspects of the present invention a COB and lighting module can comprise a UV emitting semiconductor chip or die. In this case the final application of the lighting module can be used in, for example, medical therapy such as psoriasis, UV curing of coatings, lacquers, adhesives and water and air disinfection treatment but not limited thereto. A UV emitting semiconductor chip or die can also be used for excitation of UV absorbing and visible to near infrared (NIR) emitting phosphor containing materials to produce, for example, white emission or visible to NIR spectrum. Typical semiconductor material of the die or chip in these cases are InGaN, GaN, AlGaN or AlN but not limited to these.

### COB Example 1

A COB component is disclosed which comprises a thermally conductive substrate and at least one semiconductor light emitting die bonded to the thermally conductive substrate, an electrically insulating material, as well as anode and cathode electrodes on the insulating material. The anode and cathode electrodes are wire bonded to the front side of the semiconductor die's anode and cathode. The back side of the semiconductor light emitting chip is electrically neutral. The semiconductor device is encapsulated with an optical encapsulant which may contain wavelength conversion material.

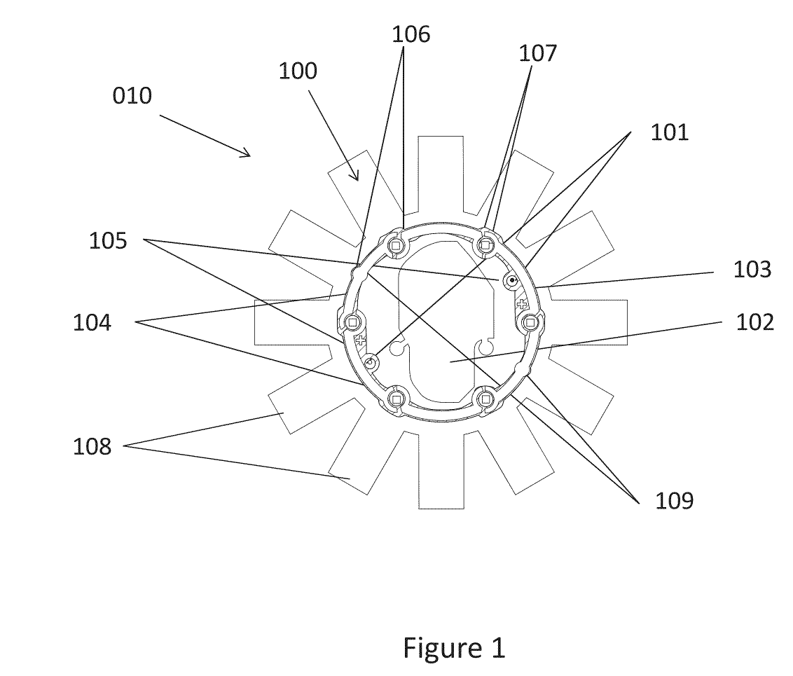

The COB module 010 of the example of the COB example 1 can be constructed in following way but is not limited to the present approach. Copper sheet metal 100 with a thickness of 0.5 mm has 2 alignment marks 101 according to FIG. 1. The metal sheet is mechanically shaped to form a central opening 102.

In a separate process FR4 laminate 103 anode and cathode circuitry 104 is fabricated and cut in shape to fit the central opening of the metal sheet. The FR4 laminate has a thickness of 0.4 mm and the top finishing of the electrical circuitry is a plated silver layer in order to be compatible with gold wire-bonding at a later stage of the assembly. The FR4 laminate has two openings 105 for alignment purposes with the copper sheet alignment marks 101. The FR4 laminate also has 6 2 mm openings 106 for later stage die bonding.

The sheet metal and the FR4 laminate circuitry are laminated according to the alignment marks 101 and the openings 105 using a commercial epoxy electronics grade adhesive. After joining the sheet metal and the FR4 laminate 6 sapphire based InGaN semiconductor light emitting chips, 45 mil×45 mil diameter each, are die bonded to the openings 106 using commercial thermally conductive die binding adhesive. The anodes and cathodes of the FR4 and the anodes and cathodes of the light emitting chips are wire bonded by using industrial wire bonder and gold wire 107.

3 mm wide and 1.5 mm high silicone encapsulant domes were dispensed on each light emitting chip, also covering the wire bonds between the chip and FR4. Immediately the laminate was then exposed for 30 seconds to UV curing to introduce initial hardening of the silicone encapsulant and then further to 3 hours of thermal curing at 150° C. to finalize the silicone hardening. In the the present example the silicone encapsulant contained 5 w-% of YAG:Ce and Nitride based phosphors. Finally the sheet metal with FR4 laminate and light emitting chips and their electrical circuitry were subject to a mechanical bunching process to result in an LED COB device with 12 heat conductive fins 108 around it. The LED COB was then subject for further processing of the lamp construction and connection of LED driver via electrical contacts 109.

### COB Example 2

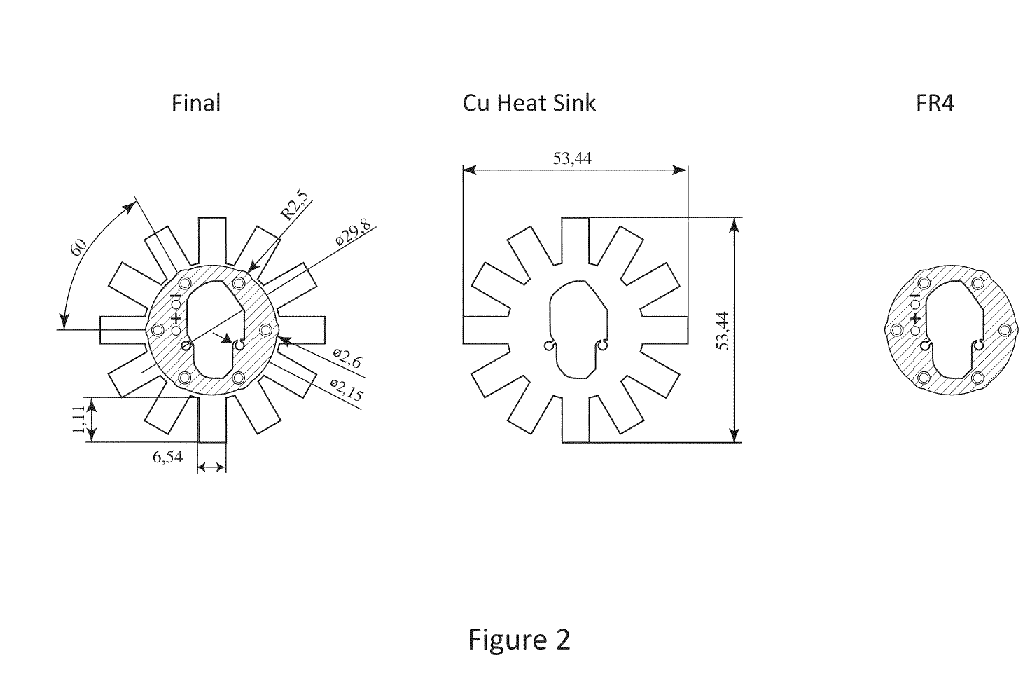

FIG. 2 shows a COB component similar to that of example 1 which comprises a thermally and electrically conductive copper substrate, at least one semiconductor light emitting die which bonded to the thermally and electrically conductive copper substrate, an electrically insulating FR4 material, an anode or cathode electrode on the insulating material. The anode or cathode electrodes are wire bonded to a front side of the semiconductor die's electrical contact. The back side of the semiconductor light emitting chip is either anode or cathode. The semiconductor device is encapsulated with an optical encapsulant which may also contain wavelength conversion material.

### COB Example 3

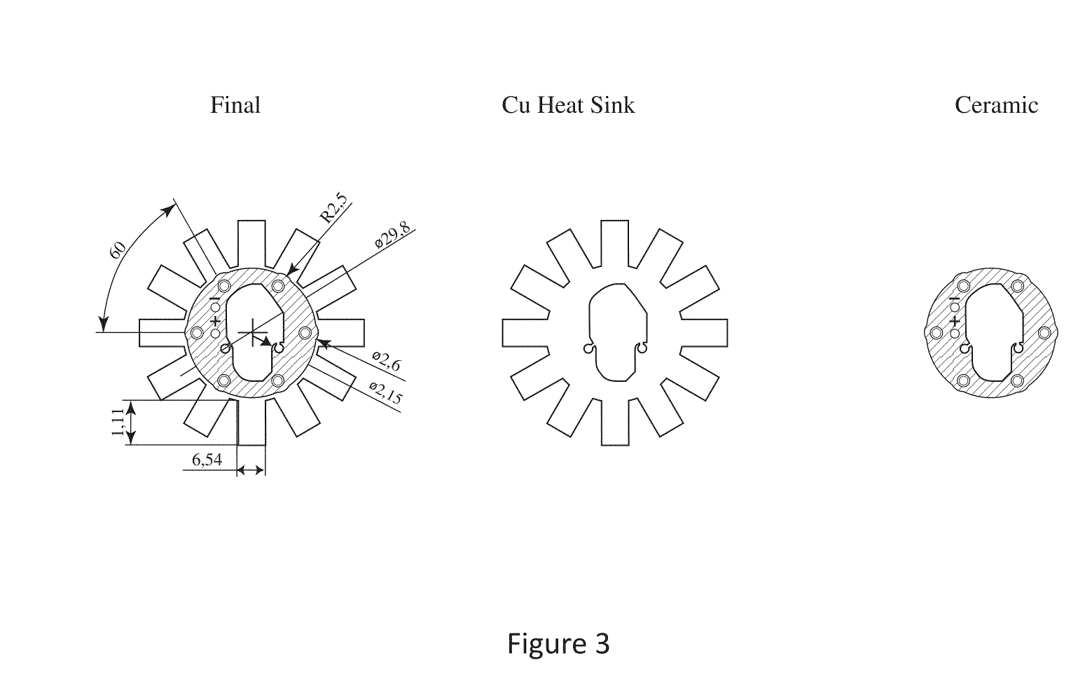

FIG. 3 shows a COB component similar to FIG. 2 but having a ceramic insulating material. The COB component comprises a thermally and electrically conductive copper substrate with separate electrical anode and cathode contacts, at least one semiconductor light emitting die is bonded to the thermally and electrically conductive substrate and an electrically insulating ceramic material. The anode or cathode electrodes of the die are the same side of the chip and those are flip-chip bonded to the anode and the cathode the thermally and electrically conductive substrates corresponding anode and cathode. The semiconductor device is encapsulated with an optical encapsulant which may also contain wavelength conversion material.

According to aspects of certain embodiments of the invention, in all above-mentioned COB constructions the light emitting die or chip is bonded to the primary heat sink with a thermally and/or electrically conductive adhesive, with eutectic bonding or with metal or metal alloy solder.

The electrically insulating material on the thermally and/or thermally conductive substrate can be a dielectric organic polymer, siloxane polymer, silicone polymer, FR4 laminate or ceramic material such as alumina, aluminum nitride or boron nitride. However, the insulating material is not limited to these as other materials having sufficient electrically insulating properties may be used in connection with the present invention. All of the above mentioned COB examples can be arranged by using copper primary heat sink substrate and laminate or ceramic dielectrics structures.

### LED Light Module Example 4:

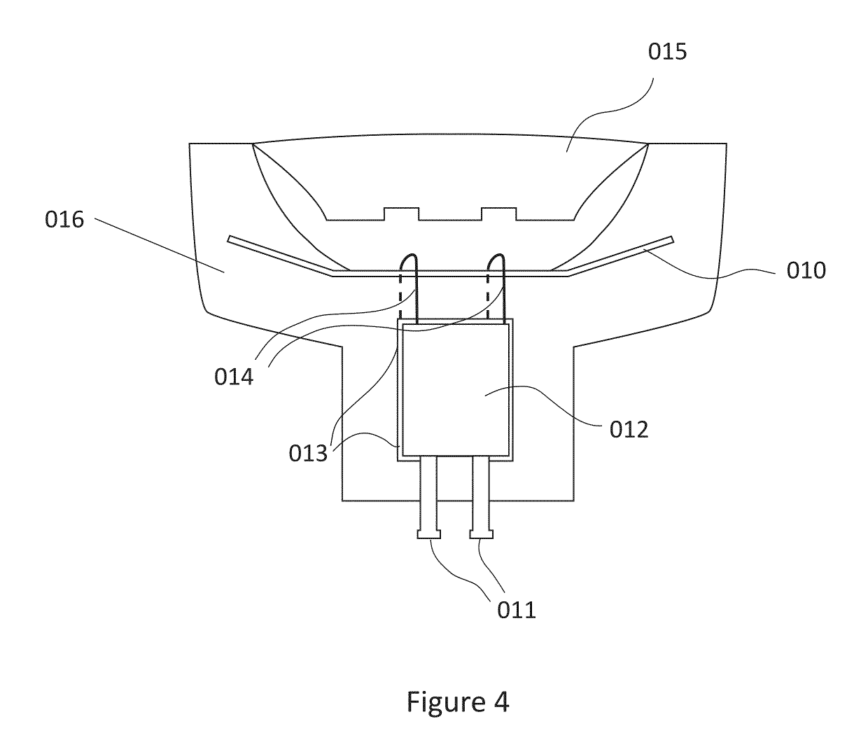

The LED COB 010 from example 1 is taken and all 12 fins 108 are first bended 120 deg upwards out of the plane, as represented in FIG. 4. The LED COB 010 is inserted into an insert injection molding device and at the same time two lighting module electrical bins 011 (GU-10 compatible) are inserted into the injection molding device as well. Standardized size GU-10 plastics secondary heat sink are extruded around the LED COB module and the electrical bins leaving an open cavity 012 for an AC/DC converter-LED driver module. Fins 108 are at least partially cover by the injection molded plastic on both side of the fins. The AC/DC converter-LED driver module 013 is inserted into the cavity so that it is in electrical connection to the electrical bins 011. Electrical wires 014 are connected from the converter-driver module to the anodes and cathodes contacts 109 of the LED COB module 010. An optical lens sealing unit 015 is attached on top on the LED COB module 010 and in connection with the molded plastic secondary heat sink.

The LED lighting module of Example 4 is not limited to GU-10 type lighting modules and can also be used in other types of modules including, for example, MR-16, E27 bulbs as well as custom shaped lamps and luminaires.

Use of the invention is advantageous in general lighting applications for high efficiency, reliable and compact lamp constructions. Especially, it is advantageous to produce LED lamp and luminaires with high color rendering index (CRI), general lighting devices comprising high R₉ value or R₉ value higher than 50 and in general white light lamps and luminaires rich with 600-800 nm emission from red light emitting phosphors.

However there are several applications for the invention beyond general lighting. Therefore, the present innovation provides an optimal emission spectrum LED component for living cells activation know for example as therapeutic, cell grow and metabolism activation, photosynthesis, photomorphogenesis due to a broad emission peak at 600 to 800 nm wavelength range. Human, animal and plant cells absorb efficiently in 600 to 800 nm wavelength range however different cells still have more selective yet relatively broad absorption bands in the given wavelength region. Due to the board emission peak of the LED COB component described by the innovation, the light energy is more efficiently transferred into the object. An embodiment of the innovation provides an LED COB component design to facilitate efficient generation of a broad emission peak at 600 to 800 nm wavelength range. Finally embodiments of the innovation provide a utilization of semiconductor quantum dots and nanoparticulate phosphor materials to obtain a preferable board emission peak at 600 to 800 nm wavelength range.

The LED device with a wavelength converter material of the partial- or complete-conversion of the LED's electroluminescence may contain a supplementary phosphor which absorbs a portion of the emission with a wavelength shorter than 500 nm and emits red/far-red light in the spectral range of 600 to 800 nm, which meets the photosynthetic and photomorphogenetic needs of plants. Such a phosphor can be an oxide, halooxide, chalcogenide, nitride or oxynitride compound activated by ions of divalent or tetravalent manganese, divalent or trivalent europium, trivalent bismuth, or divalent tin.

For example, the supplementary red component can be generated in inorganic phosphors, such as but not limited to: Mg₂SiO₄:Mn²⁺; Mg₄(F)GeO₆:Mn²⁺; (Mg,Zn)₃(PO)₄:Mn²⁺; Y₃Al₅O₁₂Mn⁴⁺; (Ca,Sr,Ba)₂Si₅N₈:Eu²⁺; Sr₂Si₄AlON₇IEu²⁺; MgO—MgF₂—GeO₂Eu²⁺; Y₂O₂S:Eu³⁺,Bi³⁺; YVO₄:Eu³⁺,Bi³⁺; Y₂O₃:Eu³⁺,Bi³⁺; SrY₂S₄Eu²⁺SrS:Eu²⁺; MgSr₅(PO)₄:Sn²⁺; (Ca): SiN₂:Ce²⁺; (Ca,Sr)SiN₂:Eu²⁺; (Ca,Ba)SiN₂,AlO:Eu²⁺; (Ca,Sr,Ba)₂Si₅N₈:Eu²⁺; Gd₃Ga₅O Cr³⁺; (Ca,Sr,Ba)₂Si₅N₈:Eu²⁺ and Gd₃Ga₅₀12:Cr³⁺.

However all wavelength conversion materials are subject to thermal quenching in some degree and in particularly long stokes shift phosphor wavelength conversion materials are susceptible to thermal quenching of conversion efficiency. Here in particular long stokes shift is considered to be more than 150 nm wavelength shift from a blue emission peak emission to red or far red wavelength region.

As with common LED devices the phosphor material is located in close proximity to the semiconductor diode, such as an InGaN chip. Therefore the phosphorous material is subject to heat produced by the semiconductor chip and resulting in non-radiative recombination. Phosphorous materials are also subject to self-heating, meaning that part of the emission from the semiconductor diode chip is absorbed by the phosphor and transformed into heat in the material. Self-heating is further increased when phosphor particles are densely packed particles and cause a lot of scattering of the diode chip emitted light. Thus, part of the scattered light energy coverts to heat, which lowers the conversion efficiency. In order to avoid thermal quenching and self-heating quenching derived conversion efficiency decrease in LED devices a novel LED component was designed. In particular the new design addresses use of light conversion materials with wavelength stokes shift more than 150 nm.

The present design comprises a plurality semiconductor diode chips with emission characteristics between 200 and 500 nm and more typically between 350 and 500 nm in a COB chip carrier. The carrier was designed to the primary heat sink and the secondary heat sink, wherein the primary heat sink can be electrically and thermally conductive and the secondary heat sink is at least partially only heat conductive. The primary heat sink is a bonding substrate for the semiconductor light emitting diode's anode and cathode contacts. The secondary substrate is a bonding substrate for the COB component, i.e, primary heat sink. The secondary substrate is also part of the lighting module mechanical construction and is electrically insulating the COB component from the ambient. The COB component is only electrically connected from an anode and a cathode to DC or AC circuitry, e.g. LED driver or AC-DC converter.

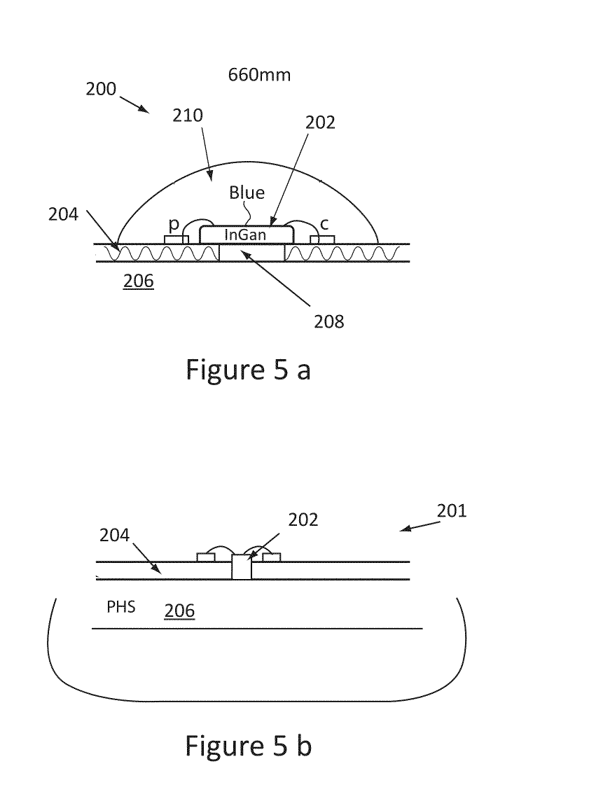

According to a first Light Emitting Diode (LED) lamp embodiment there is disclosed herein an LED lamp comprising at least one light emitter component, a primary heat sink formed of a material having a first thermal conductivity, a secondary heat sink, intimately bonded to at least a portion of the primary heat sink, said secondary heat sink formed from at least one material having a second thermal conductivity, a dielectric material partially covering a first surface of the primary heat sink and said dielectric material supporting the at least one light emitter component, a volume between the component and the first surface of the primary heat sink which is void of dielectric material which thermally exposes the component to the primary heat sink, and wherein the primary heat sink is electrically insulated from the environment. An example is shown in FIG. 5a.

FIG. 5a shows the cutaway of an LED lamp 200 which has an indium gallium nitride (InGaN) diode 202 which emits blue light in the 660 nm spectrum. The diode is supported by an insulating layer such as a dielectric material 204. Examples of suitable dielectrics are Boron Nitride and Aluminum oxide. The dielectric material 204 supports the diode 202 and is covering at least a first portion of a primary heat sink 206. Examples of suitable primary heat sinks are copper and Aluminum. an anode and cathode are also supported on the dielectric material 204 and connect the diode 202 to the lamp circuitry.

A volume 208 of dielectric material 204 is missing below the diode 202. As discussed above, a problem in current LED lamps is the over heating and poor thermal dissipation of diodes. A major reason is that in standard lamps a diode sits directly on an insulator material. Therefore, heat is either incapable of efficiently dissipating from the area where the diode is in contact with the insulating later or is poorly dissipated due to the insulating properties of the insulating material. One reason for placing the a diode away from a primary heat sink in that a good heat conductor is typically a good electrical conductor, or prohibitively expensive. Therefore, to avoid shorts it has been conventional wisdom to electrically separate the diode from the primary heat sink.

However, as described herein, the primary heat sink is kept completely electrically insulated from the environment by a secondary heat sink. An example of which is shown in FIG. 4. The copper fins 108 of the COB 010 act as the primary heat sink 206 for the diodes. An electrically insulating material, such as plastic, 016, completely surrounds the primary heat sink which at least partially insulates the primary heat sink from the environment. In the case of FIGS. 4 and 5 the diode is encapsulated in an encapsulating material 015 and 210 respectively. Between the encapsulating material and the secondary heat sink, the primary heat sink is completely electrically insulated from the environment. Furthermore, the fins of the primary heat sink are capable of efficiently transferring the heat from the bottom of the diode out and to a secondary heat sink which can be an inexpensive material, e.g. plastic, with a great surface area. As in the case of FIG. 4 the secondary heat sink can effectively form at least a portion of the housing of the lamp.

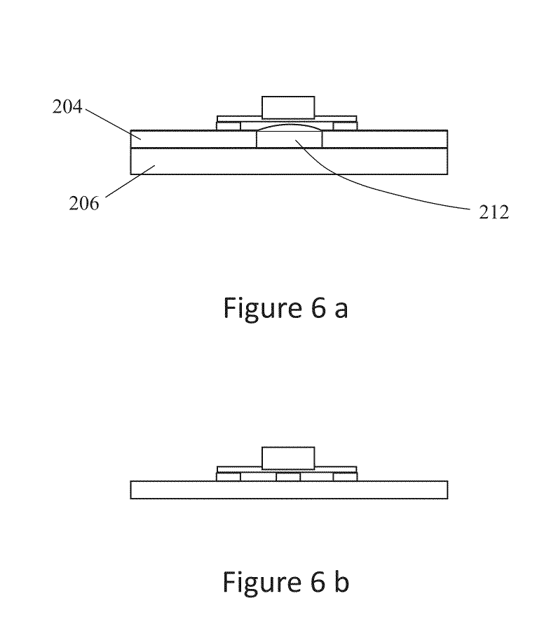

The volume 208 can be created by removing a portion of dielectric material from the primary heat sink where, or near where the diode will be placed. Similarly, the dielectric material may be printed on the primary heat sink with a volume missing. A purpose of the volume is to facilitate the transfer of heat from the bottom of the diode to the primary heat sink. Therefore, the volume may be empty, filled with a gas or filled with a high thermal conductivity adhesive 212. In such an example the high thermal conductivity adhesive 212 can be in contact with both the light emitter component and the first surface of the primary heat sink 206. As the primary heat sink 206 is completely electrically insulated from the environment it is possible for the filler to make an electrical connection between the diode and the primary heat sink with little or no ill effect. FIG. 6a shows an example of such. Additionally, FIG. 6b shows an example similar to that of FIGS. 5a and 6a wherein the dielectric layer only covers a portion of the primary heat sink and can even essentially only be to support the diode, anode, cathode and any desired circuitry.

According to another embodiment there is described herein a Light Emitting Diode (LED) lamp comprising at least one light emitter component, a primary heat sink, in direct contact with the light emitter component, said primary heat sink formed of a material having a first thermal conductivity, a secondary heat sink, intimately bonded to at least a portion of the primary heat sink, said secondary heat sink formed from at least one material having a second thermal conductivity, and wherein the primary heat sink is electrically insulated from the environment. An example is shown in FIG. 5b.

As discussed above, the presence of the secondary heat sink and the circumstance that the primary heat sink in completely electrically insulated from the environment, it is possible for a diode 202 to actually be mounted directly to a primary heat sink 206. In such an example a dielectric 204 is still present to support the anode and cathode and any desired circuitry above the primary heat sink. However, with the diode base directly in contact with the primary heat sink it is possible to dissipate heat from the bottom of the diode extremely efficiently.

Further examples which relate to either the embodiment with or with out a void below the diode are as follows. A lamp may further comprising a dielectric material on at least a first face of the primary heat sink containing the light emitter component, said dielectric material at least partially surrounding said light emitter component. Additionally, as discussed above, an LED lamp may further comprise electrical connections mounted on the dielectric material and connected to said light emitter component.

The primary heat sink can be a block of metal or metalloid material having high thermal conductivity and having a first face surface area, thickness and second face surface area, said second face opposite the first. Additionally, at least one light emitter component can be in direct contact with the first surface of the primary heat sink and the remaining surface area of the first face is covered by a dielectric material.

The second face of the primary heat can be intimately bonded to the secondary heat sink. For example as discussed with respect to FIG. 4 where the plastic 016 is molded around the COB 010. Similarly, all non-first surfaces of the primary heat sink are intimately bonded to the secondary heat sink.

An LED lamp may further comprise an encapsulating material which covers at least the light emitting portion of the at least one light emitter component. The secondary heat sink, dielectric material and encapsulating material may combine to completely electrically isolate the primary heat sink from the environment.

The first and second surfaces of the primary heat sink can be essentially flat, bent, angled curved or of practically any other geometry. The primary heat sink may have or be void of fins. Additionally, the primary heat sink can be comprised completely or at least partially of Copper, Aluminum or another electrically and thermally conductive material.

As the secondary heat sink will virtucally always have a greater surface area compared to that of the first, the second thermal conductivity can be lower than the first. For example, the surface area of the secondary heat sink can be 5-100 times, preferably 10-50 times greater than the surface area of the primary heat sink. Additionally, the secondary heat sink may also include, or not include, a fin or fins. Furthermore, the secondary heat sink can be comprised of an electrically insulating material, of a plastic or polymer material. It can be formed by a heat molded material molded directly around at least a portion of the primary heat sink.

The at least one of the light emitter components can be comprised of, for example, InGaN or, GaN, AlGaN or AlN. The LED lamp may also comprise encapsulate material, said material may comprise red phosphor. At least one light emitter component, or the at least one light emitter component and encapsulating material combined, can be capable of providing a light output spectrum with at least a first output peak in the wavelength range from 600 to 800 nm, said peak having a full width at half maximum of at least 50 nm; a second optional output peak in the wavelength range from 200 to 500 nm, and a third optional output peak in the wavelength range from 700 to 1000 nm. The full width at half maximum can be less than 50 nm for the second optical light output peak at 200-500 nm wavelength range. Additionally, the output emission in the wavelength range from 600 to 800 nm can be phosphorescent emission and the optional output emissions in the wavelength ranges of 200-500 nm and 700-1000 nm, respectively, are electroluminescent light output emissions.

The optical emissions output in wavelength range of 600-800 nm can comprise, or consist of two phosphorescent emission peaks, both with a full width at half maximum of at least 50 nm. The second optional light output peak in the wavelength range of 200-500 nm can be obtained with at least two semiconductor diodes chips and the peak emission wavelength of the chips can be at least 5 nm apart from each other.

The second optional light output peak in the wavelength range of 200-500 nm can be obtained with a plurality of semiconductor diodes comprising; at least one semiconductor diode with a peak wavelength emission below 450 nm, at least one semiconductor diode with a peak wavelength emission between 445-465 nm; and at least one semiconductor diode with a peak wavelength emission above 460 nm.

The light emitter component can comprise at least 10 individual semiconductor components with electro-luminescent emissions between 200-500 nm. The light emitter component can also comprise a plurality of semiconductor diode chips with emission characteristics between 200-500 nm and more typically between 350-500 nm in a plastic leaded chip carrier. A carrier can comprise an anode, a cathode and a through package metallic heat sink slug. A plastic leaded chip carrier can comprise a cavity wherein the heat sink, such as a metallic slug heat sink, can be located, and bonded to the primary heat sink.

The light emitter component can comprise a plurality of diodes, preferably semiconductor diode chips, at least a portion of which being positioned from each other at a distance amounting to at least the chip's own width. The light emitter component can also comprise a plurality of diodes, preferably semiconductor diode chips, said diodes or semiconductor diode chips not being centrally aligned.

The semiconductor diode chips can be coated with a silicone encapsulate containing nano particulate wavelength conversion material. The LED lamp can also comprise being a light output spectrum with at least one peak intensity in the wavelength range of 600-800 nm with a full width at half maximum at least 50 nm; a second optional optical light output peak in the wavelength range of 200-500 nm; and a third optional output peak in the wavelength range of 700-1000 nm wavelength range, and at least one emission peak can be obtained by quantum dot light conversion material.

The LED lamp can also comprise having a light output spectrum with at least one peak intensity in the wavelength range of 600-800 nm with a full width at half maximum at least 150 nm; a second optional optical light output peak in the wavelength range of 200-500 nm; and a third optional output peak in the wavelength range of 700-1000 nm wavelength range, and at least one emission peak can be obtained by nano particulate phosphor light conversion material.

Furthermore, a lamp may comprise a plurality of light emitting components are connected to each other electrically in parallel and at least one additional light emitting components are electrically connect to others in serial. The electrically parallel connected light emitting components can be InGaN semiconductors and the at least one serial or parallel connected light emitting component can be an AlGaAs or AlGaInP semiconductor diode.

According to certain embodiments it is possible to obtain a preferable broad wavelength spectrum by using semiconductor quantum dot materials as a light conversion material from shorter wavelength (200-500 nm) to higher wavelength (600-800 nm). The semiconductor quantum dot materials are also susceptible for thermal quenching in the wavelength conversion efficiency. Therefore the LED component arrangement as disclosed herein and accordingly to FIG. 1 is preferable for an electroluminescent diode with emission wavelength below 500 nm and the emission wavelength to be converted to 600-800 nm wavelength range. CdSe—ZnS (core-shell) quantum dot nanoparticles for example are applicable for the the purpuse to have 300-500 nm wavelength electroluminescence conversion to 600-800 nm wavelength range. According to certain embodiments it is beneficial to use a broad distribution range of quantum dots as wavelength light conversion material and therefore obtain emission spectrum with full width at full maximum broader than 50 nm at 600-800 nm wavelength range.

It is also possible to use nanoparticulate light conversion phosphor materials in applications of long stokes shift wavelength conversion. Due to smaller particle size the quantity of the wavelength converter can be reduced per volume to achieve sufficient wavelength conversion from 300-500 nm wavelength region to 600-800 nm wavelength region. Again, higher conversion efficiency can be achieved when compared to conventional LED packages.

A COB component can also be designed so that the component contains at least two types of light emissive semiconductor diode chips. For example, at least one InGaN diode chip and at least one AlGaAs or AlGaInP diode chip. It should be noted however that the present innovation is not limited to these semiconductor diode types. The semiconductor diode chips can be electrically connected in serial and/or parallel. According to certain embodiments it is preferable that the first diode emits at a range of 300 to 500 and the second diode emits at a wavelength range of 600 to 1000 nm. More specifically the second diode's emission peak can be in a wavelength range of 640 to 700 nm, 720 to 740 nm or 870 to 900 nm. There can also be three different types of LEDs, all having different characteristic spectral emission peaks.

Conventionally used single semiconductor chips (or 2 or 3 semiconductor chips) containing high brightness LED's produce very point source type emission from the LED package. This high brightness point source emission can be “diffused” by using specially designed optics in connection with the LED or using specially designed light guiding/diffusing sheets/films in close proximity of the LED package. The use of complicated optics and light management optics/sheet/films impacts the cost of the final LED lamp and furthermore reduces efficiency of the LED package/lamp due to losses at the optical interfaces.

Particularly when an LED lamp is used for the therapeutic, cell grow action, metabolism activation and photomorphogenesis purposes, especially with human and animals, it can be important that there is sufficient intensity uniformity in terms of radiation intensity at the treated surface area. In some cases the point source like treatment light can be preferred but in general uniform distribution of light is preferred. Described herein is the usage of a multi semiconductor chip high brightness LED COB component, which does not suffer from the above mentioned “single point source” issues. High intensity uniformity can be achieved without using any optics or potentially using very simple diffuser sheet in connection with the final LED lamp. This results in an excellent approach to produce LED light sources which produce uniform light intensity distribution even from very close proximity illumination/treatment distances.

As described herein, the multi semiconductor chip high brightness LED COB can be constructed from several individual semiconductor chips. Depending on the architecture of the LED package, individual chips can be connected in series or parallel or both within one individual LED package. Furthermore, it is possible to use one or several type individual semiconductor chips to construct the multi chip LED packages. These individual chips may have also different emission wavelengths within the one multi chip LED package. In some cases it might be preferable to also use zehner diodes or other control mechanisms within one LED package to take into account possible failure of single semiconductor chips in the LED package.

The above mentioned LED COB components are used in the actual final LED lamp fixtures. In one LED lamp fixture there can be one or more LED COBs used. Within the LED lamp these individual COBs can be connected in series or parallel depending on the desired electrical properties (voltage, current and power) of the final LED lamp. Again, it might be preferable to use zehner diodes or other control mechanisms within LED lamp between the individual LED packages to take into account possible failure of single LED package in the LED lamp.

The LED lamp fixtures can be designed to have different forms. In general they can be identified as so called general room lighting providing LED lamps and then closer proximity used LED lamps. The general lighting type of LED lamps fixture can be tube light lamp fixtures (used similar way to the fluorescent tubes) and panel lights (assembled to the ceiling of the room) and also block lights like example high pressure sodium lamps used in greenhouse cultivation (assembled to high altitude in greenhouse). Closer proximity LED lamps can be example face treatment/illumination lamps and “treatment pens”, which are both used in very close proximity of face or skin. The body of the LED lamp fixture needs to be able to function as a heat sink and to be able to efficiently dissipate the heat generated by the LED packages.

In greenhouses the LED lamps can be used either as ceiling installed general lights or used in closer proximity depending on what type of line and what is being grown in the facility. Also it is possible use the LED lamps in multilayer growth installations and also as inter lights in between plants. Furthermore, it is possible to use the LED lamps in greenhouses where there are no natural light available or natural light is available part of the day. The LED lamps can be used also in farms for example cows and chickens. By the control of the day length and also control of the light spectrum it is possible to effect on the growth and milk production or egg incubation production of cows and chickens, respectively. Also the quality of the light influences example on the composition of the milk. The LED lights can be used also for skincare and wound healing purposes and cancer pain therapy for example horses or humans, but not limited to these. Furthermore, the LED light can be used in an artificial egg incubation process or in poultry farming industry as a growth and feeding stimulant.

Based on the above, according to an example embodiment, the present technology provides a method of aiding in a photo stimulation process comprising the steps of providing a first light output spectrum with at least a first output peak in the wavelength range from 600 to 800 nm, said peak having a full width at half maximum of at least 50 nm; a second optional output peak in the wavelength range from 200 to 500 nm, and a third optional output peak in the wavelength range from 700 to 1000 nm, wherein said first and said second and third optional outputs are provided from an LED component.

The method can be used in aiding a process selected from, e.g., the group of therapeutic, cell grow action, metabolism activation photosynthesis, photomorphogenetic and combinations thereof.

The examples and embodiments disclosed herein are illustrative of the concept of the present invention. Those of ordinary skill in the art will recognize variations and additional uses for the present invention which while not explicitly disclosed herein none the less do not depart from the scope of the present invention. Specifically, features described with respect to certain embodiments or examples may be utilized interchangeable, or in conjunction with other embodiments and examples without departing from the scope of the invention. Additionally, for example, the circuitry on a COB or can include active or passive components such as, for example, drivers, capacitors, resistors, current controllers, voltage controllers or a combination thereof.

It is to be understood that the embodiments of the invention disclosed are not limited to the particular structures, process steps, or materials disclosed herein, but are extended to equivalents thereof as would be recognized by those ordinarily skilled in the relevant arts. It should also be understood that terminology employed herein is used for the purpose of describing particular embodiments only and is not intended to be limiting.

Reference throughout this specification to “one embodiment” or “an embodiment” means that a particular feature, structure, or characteristic described in connection with the embodiment is included in at least one embodiment of the present invention. Thus, appearances of the phrases “in one embodiment” or “in an embodiment” in various places throughout this specification are not necessarily all referring to the same embodiment.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary. In addition, various embodiments and example of the present invention may be referred to herein along with alternatives for the various components thereof. It is understood that such embodiments, examples, and alternatives are not to be construed as de facto equivalents of one another, but are to be considered as separate and autonomous representations of the present invention.

Furthermore, the described features, structures, or characteristics may be combined in any suitable manner in one or more embodiments. In the following description, numerous specific details are provided, such as examples of lengths, widths, shapes, etc., to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

While the forgoing examples are illustrative of the principles of the present invention in one or more particular applications, it will be apparent to those of ordinary skill in the art that numerous modifications in form, usage and details of implementation can be made without the exercise of inventive faculty, and without departing from the principles and concepts of the invention. Accordingly, it is not intended that the invention be limited, except as by the claims set forth below.

1. A Light Emitting Diode (LED) Chip-on-Board (COB) comprising,
a thermally and electrically conductive substrate,
at least one semiconductor light emitting die bonded to the thermally and electrically conductive substrate,
an electrically insulating material,
an anode or cathode electrode on the insulating material, wherein said anode or cathode electrodes are wire bonded to a first side of the semiconductor light emitting die's electrical contact, and the opposite side of the semiconductor light emitting chip is either anode or cathode, and
wherein the semiconductor device is encapsulated with an optical encapsulate.

2. The LED COB according to claim 1, wherein the optical encapsulate contains wavelength conversion material.

3. The LED COB according to claim 1, wherein the thermally and electrically conductive substrate is a metal sheet.

4. The LED COB according to claim 1, wherein the thermally and electrically conductive substrate has at least one alignment marking and the electrically insulating material has at least one corresponding marking opening.

5. The LED COB according to claim 1, wherein the thermally and electrically conductive substrate has a central opening.

6. The LED COB according to claim 5, wherein the electrically insulating material is either an FR4 laminate or a ceramic material having electrical circuitry on one side and a central opening corresponding to the central opening of the thermally and electrically conductive substrate.

7. The LED COB according to claim 6, wherein the top finishing of the electrical circuitry of the electrically insulating material is a plated silver layer.

8. The LED COB according to claim 6, wherein the electrical circuitry of the electrically insulating material comprises at least one passive or active element selected from the group of: a driver, a capacitor, a resistor a current controller or a voltage controller.

9. The LED COB according to claim 1, wherein the electrically insulating material has a plurality of openings for die bonding.

10. The LED COB according to claim 9, wherein at least one of the plurality of openings for die bonding is not for alignment with the thermally and electrically conductive substrate.

11. The LED COB according to claim 9, wherein the at least one semiconductor light emitting die is bonded to an opening for die bonding in the electrically insulating material.

12. The LED COB according to claim 1, wherein the electrically insulating material is bonded to the thermally and electrically conductive substrate having the alignment marks and openings aligned.

13. The LED COB according to claim 1, wherein the thermally and electrically conductive substrate has at least one fin.

14. The LED COB according to claim 13, wherein the electrically insulating material is centrally deposed between a plurality of fins of the thermally and electrically conductive substrate.

15. The LED COB according to claim 13, wherein at least one of the fins is bent at an angle towards or away from the electrically insulating material.

16. (canceled)
